(19) United States
(12) Patent Application Publication
(10) Pub. No.: US 2022/0192005 A1
(43) Pub. Date: Jun. 16, 2022

(54) HIGHLY OPTIMIZED ELECTRONIC MODULE DESIGN

(71) Applicant: BAE Systems Information and Electronic Systems Integration Inc., Nashua, NH (US)

(72) Inventors: Jason M. Bugeau-Medas, Dover, NH (US); Scott P. Rogers, Nashua, NH (US); Eric A. Skogsholm, Merrimack, NH (US)

(73) Assignee: BAE Systems Information and Electronic Systems Integration Inc., Nashua, NH (US)

(21) Appl. No.: 17/123,517

(22) Filed: Dec. 16, 2020

(51) Int. Cl. H05K 1/02; H05K 3/28

(52) U.S. Cl. CPC H05K 1/0209; H05K 2201/10409; H05K 3/284; H05K 3/282

(57) ABSTRACT

An electronic module utilizing a bathtub heatsink and single-cover design to provide improved thermal management and fault isolation while minimizing cost and complexity. The electronic module may also provide for better galvanic corrosion prevention through the utilization of a single finish on the components thereof. Further provided may be an electronic module design utilizing a single set of fasteners, which may further reduce assembly cost and complexity while further providing increase galvanic corrosion prevention.

### STATEMENT OF GOVERNMENT INTEREST

This invention was made with government support under Contract Nos. 6534538260 and 6500005205 awarded by the U.S. Navy. The government has certain rights in the invention.

### TECHNICAL FIELD

The present disclosure relates to an electronic module to maximize producibility and fault isolation while minimizing cost and complexity. More particularly, in one example, the present disclosure relates to an electronic module designed with improved thermal management and fault isolation while reducing cost, complexity, and preventing galvanic corrosion between the dissimilar metals contained therein. Specifically, in another example, the present disclosure relates to an electronic module utilizing a single floating cover in conjunction with a bathtub heatsink for improved thermal management and fault isolation while providing lower cost and complexity and reducing galvanic corrosion through the use of a single finish.

### BACKGROUND

An electronic module is a self-contained assembly of electronic components that typically includes a circuit board and/or associated wiring to perform a defined task, and may be linked to other such units to form a larger system. Electronic modules, typically due to the current flowing therethrough, tend to generate a large amount of heat which must be managed in that the electronic components thereof must be cooled to prevent overheating and failure. As most modules are typically self-contained, external cooling is often not ideal or available, therefore most electronic modules tend to employ a heatsink arrangement to conductively cool the electronic components of the circuit board and components contained therein.

Existing solutions for thermal management of an electronic module typically includes the utilization of a two-cover design, which may add tolerances to the stackup between top-cooled components and a pedestal. This tends to require a gap filler material that is typically applied as a liquid, which can add further complication to the assembly process, rework process, and/or ongoing sustainment and maintenance of the module. These two-cover designs can also be used with gap pads to help manage the thermal conductivity and regulation of the module. However, the addition of gap pads into a two-cover design can further complications such as deflection of one or both covers, which, in some cases, may lead to the module no longer fitting in the allotted space within a larger system.

Assembling current modules with a two-cover design typically involves multiple steps including multiple sets of fasteners. Specifically, a first set of fasteners is commonly used to connect the circuit board to a heatsink. Then each cover is connected to the heatsink using two separate sets of fasteners. Thus, assembly of a two-cover module typically utilizes multiple assembly steps and three sets of fasteners. These steps are performed in addition to finishing steps and application of gap filler materials, thus making the assembly process long and complex.

Additionally, these designs tend to utilize dissimilar metals with some metals having better electrical conductivity properties and some having better thermal conductivity properties. These dissimilar metal combinations are used to enhance performance and efficiency; however, the close relationship of dissimilar metals is known to cause galvanic corrosion over time, again resulting in damage to or failure of the module. Often, thermal management of a module utilizes the printed board itself as a heat path, which tends to require a metal-to-metal interface at the mounting locations. Therefore, to prevent galvanic corrosion, current modules with a two-cover design tend to dual-plate (i.e. finish) the printed board, the heatsink, and/or both covers to minimize dissimilar metal contact at these metal-to-metal interfaces. This plating process is both costly and time consuming and is further prone to defects, which can defeat the corrosion-preventing properties of the plating in the first place. Thus, the average lifespan of a current electronic module utilizing a two-cover design without a dual finish scheme tends to be approximately a few years, typically less than seven to ten years.

For systems that are lower cost, have a low life expectancy, and/or are prone to earlier failure in other aspects other than the electronic modules, a lifespan in the seven to ten year range may be suitable or acceptable; however, even in such systems, the assembly costs and assembly complexity remains high. For example, for personal consumer electronics such as televisions or the like, an electronic module with a seven year lifespan may be sufficient as the television itself might only be expected to effectively perform for five to seven years before becoming outdated or experiencing failure with other components.

In more complex and/or more critical applications, a seven to ten year lifespan for electronic modules may be dangerous and/or extremely costly. For example, in applications such as electronic warfare, defense, and/or military equipment, the failure of an electronic module may be catastrophic to the system, the machinery or unit utilizing the system, and/or any to operators thereof. According to one example, wherein an electronic module is utilized in electronic warfare, it may be part of a system installed in an aircraft. Early failure of a module in such an installation may be catastrophic. For example, the failure may cause the aircraft to be unable to deploy defensive measures in the face of a threat and may result in damage or destruction of the aircraft and may further result in injury or other harm to any pilots or crew thereof.

### SUMMARY

The present disclosure addresses these and other issues by providing an electronic module utilizing a bathtub heatsink and single-cover design to provide improved thermal management and fault isolation while minimizing cost and complexity. The electronic module may also provide for better galvanic corrosion prevention through the utilization of a single finish on the components thereof. Further provided may be an electronic module design utilizing a single set of fasteners, which may further reduce assembly cost and complexity while further providing increase galvanic corrosion prevention.

In one aspect, an exemplary embodiment of the present disclosure may provide an electronic module comprising: a cover; a printed board with a first side and a second side; at least one conductive ground pad on the first side of the printed board between the cover and the printed board; at least one active component on the second side of the printed board; a heatsink defining a basin for containing the printed board therein having at least one pedestal corresponding to each of the at least one active components; at least one gap pad between a top of each of the at least one active component and the at least one corresponding pedestal of the heatsink; and a plurality of captive fasteners operable to secure the cover, printed board, and heatsink together as a single unit. This exemplary embodiment or another exemplary embodiment may further provide wherein the at least one gap pad is operable to draw heat away from the top of the at least one active component and into the corresponding pedestal of the heatsink. This exemplary embodiment or another exemplary embodiment may further provide wherein the heatsink further comprises: a thermally conductive material layer within the heatsink operable to direct heat away from the top of the at least one active component. This exemplary embodiment or another exemplary embodiment may further provide wherein the thermally conductive material layer is Annealed Pyrolytic Graphite. This exemplary embodiment or another exemplary embodiment may further provide wherein the heatsink further comprises at least one rail interface operable to connect to a rail of an associated system to dissipate heat from the thermally conductive material layer to the at least one rail. This exemplary embodiment or another exemplary embodiment may further provide wherein the cover, printed board, and heatsink each have a single finish applied thereto. This exemplary embodiment or another exemplary embodiment may further provide wherein the single finish of the cover, printed board, and heatsink are selected to be an optimal finish for each of the cover, printed board, and heatsink. This exemplary embodiment or another exemplary embodiment may further provide wherein the module is free of dissimilar metal-to-metal interfaces. This exemplary embodiment or another exemplary embodiment may further provide wherein the printed board further comprises at least one testable component on the first side thereof, wherein there are no testable components on the second side thereof. This exemplary embodiment or another exemplary embodiment may further provide wherein all active components of the at least one active component are on the second side of the printed board.

In another aspect, an exemplary embodiment of the present disclosure may provide a method of thermal management of an electronic module comprising: generating heat through the operation of at least one active component of a printed board; drawing the heat through a thermal gap pad and away from a top of the at least one active component and into a corresponding pedestal of a heatsink; directing the heat from the pedestal into a thermally conductive core layer of the heatsink; and dissipating the heat out from a rail of an associated system through a rail interface of the heatsink. This exemplary embodiment or another exemplary embodiment may further provide securing a floating cover, the printed board, and the heatsink together as a single unit with a plurality of captive fasteners prior to generating heat through the operation of the at least one active component on the printed board. This exemplary embodiment or another exemplary embodiment may further provide applying a single finish to the cover, printed board, and heatsink. This exemplary embodiment or another exemplary embodiment may further provide wherein the single finish of the cover, printed board, and heatsink are selected to be an optimal finish for each of the cover, printed board, and heatsink.

### BRIEF DESCRIPTION OF THE SEVERAL VIEWS OF THE DRAWINGS

Sample embodiments of the present disclosure are set forth in the following description, are shown in the drawings and are particularly and distinctly pointed out and set forth in the appended claims.

FIG. 1 (FIG. 1) is a top right side isometric perspective exploded view of an electronic module according to one aspect of the present disclosure.

FIG. 2 (FIG. 2) is a top elevation cross sectional view of an electronic module looking into an assembled module from the top with the sidewall of the heatsink and cover removed according to one aspect of the present disclosure.

FIG. 3 (FIG. 3) is a close up view of the section of the electronic module indicated in FIG. 2 according to one aspect of the present disclosure.

FIG. 4 (FIG. 4) is a partial top left cross section operational view of an electronic module looking into an assembled module from the top left with the sidewall of the heatsink and cover removed showing the primary thermal conductivity path according to one aspect of the present disclosure

Similar numbers refer to similar parts throughout the drawings.

### DETAILED DESCRIPTION

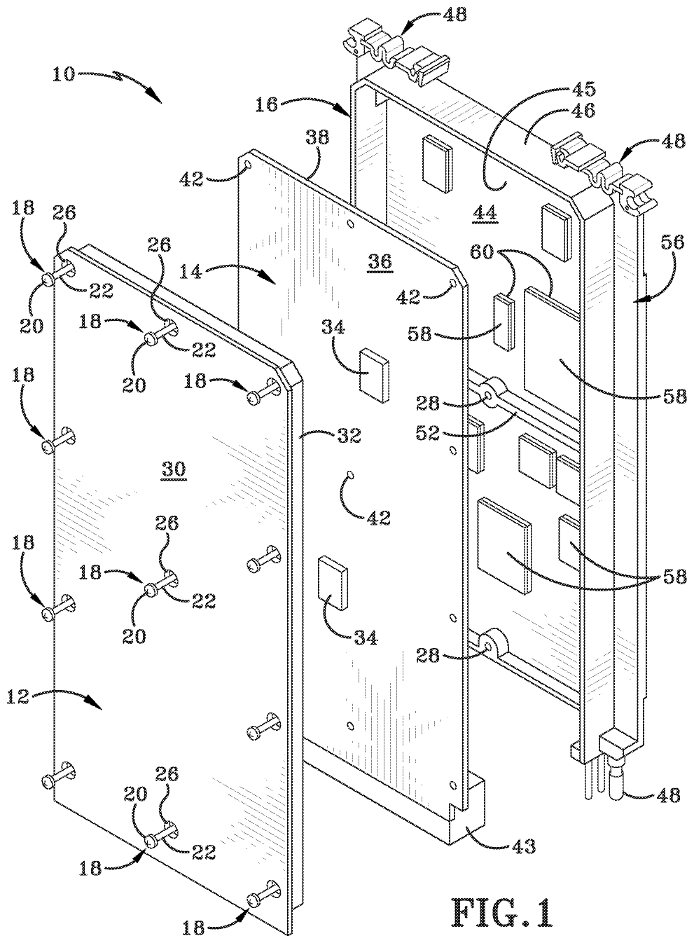

With reference to FIGS. 1-3, an electronic module is shown and generally indicated at reference 10. Module 10 may include a cover 12, a circuit board or printed board 14, and a heatsink 16.

Module 10 may be operably connected through the use of captive fasteners 18, which may be captive screws 18 or the like. Captive screws 18 may further include a head 20, a body 22, and a threaded portion 24 (best seen in FIG. 3) and may be operable to connect all components, namely cover 12, printed board 14, and heatsink 16, together into a single module 10 utilizing a single set of captive screws 18, as discussed further below.

Cover 12 may be a floating cover operable to connect with printed board 14 and heatsink 16 to form module 10. Cover 12 may be constructed of any suitable material including aluminum or other similar metals or materials. As discussed further herein, cover 12 does not necessarily need to be operable to conduct heat, therefore, it may be selected and constructed of a non-thermally conductive material or a material with lower thermal conductivity than other components described herein.

Cover 12 may further include a series of apertures 26 defined therein, which may be operable to allow captive screws 18 to pass therethrough for operable connection to printed board 14 and heatsink 16. Captive screws 18 may further secure module 10 through the engagement of threads 24 with a series of threaded receivers 28 on heatsink 16, as discussed further below. Cover 12 may have a back plate 30, which may be generally planar and may have a sidewall 32 extending perpendicularly therefrom and generally surrounding a perimeter of back plate 30 on one side thereof. In particular, sidewall 32 may generally surround the perimeter or substantially the perimeter of back plate 30 and may partially enclose a volume therein on the side of cover 12 oriented towards printed board 14, as best seen in FIG. 1. This partially-enclosed volume may provide clearance between components on or carried by printed board 14, such as conductive ground pads 34, as discussed further below.

Sidewall 32 may further be configured as dictated by the desired implementation to include one or more sections having varying heights or profiles to accommodate features of printed board 14 and/or heatsink 16 to further facilitate the connection of cover 12 thereto. For example sidewall 32 may include gaps, ribs, supports, or other similar variations as desired. It will therefore be understood that such features may be in any suitable or desired position as dictated by the desired configuration and implementation.

Printed board 14 may be a circuit board including a printed circuit board (PCB) and may have a first side 36, which may be the side oriented towards cover 12 and a second side 38, which may be the side oriented towards heatsink 16 and opposite first side. Printed board 14 may have various components on either first side 36 and/or second side 38; however, it is contemplated that as used herein, active components 40 that generate all or substantially all of the thermal activity or heat, are contemplated to be connected to or carried by printed board 14 on second side 38 thereof as these active components 40 are the elements requiring cooling and/or thermal management as best accomplished by their interaction and placement relative to heatsink 16, as discussed further herein. According to one aspect, all ball grid array (BGA) components may be installed on second side 38 of baseboard while all parts and components that are able to be probed during testing and maintenance, for example, caps, resistors, and the like, may be installed on the first side 36 of printed board 14. This may facilitate easier and faster maintenance, including shorter debug times.

First side 36 of printed board 14 may further include one or more conductive ground pads 34, which may be electrically conductive and operable to provide a ground path from the metal cover 12 and heatsink 16 to the printed board 14 and allow electrical current flowing therethrough to be grounded and prevent interference or disruptions caused therefrom. Similarly, other low-heat generating elements or components may also be carried on first side 36 of printed board 14 as dictated by the desired implementation.

Printed board 14 may further include a connector 43 and other related components for operable connection to a related system. According to one aspect, connector 43 may be any suitable data and/or power connector operable to connect printed board 14 to an associated connector. According to another aspect, connector 43 may be a line replaceable module (LRM) connector. According to yet another aspect, connector 43 may be a shielded, high-density, high-speed, modular interconnect system optimized for differential pair architectures that is compatible with any suitable architecture, such as VITA 46 or VITA 48 standard architectures. For example, connector 43 may be a VPX LRM connector that may be commercially available and integrated into printed board 14. Connector 43, as used herein, is to be understood to include any suitable or necessary counterparts within an associated system in which module 10 is installed.

With reference to FIGS. 1-3, but as best seen in FIG. 3, printed board 14 may further include a series of screw apertures 42 defined therein which may be aligned with apertures 26 of cover 12 and threaded receivers 28 of heatsink 16 to allow captive screws 18 to pass therethrough and to further facilitate the construction and connection of cover 12, printed board 14 and heatsink 16 into a single module 10, as discussed below.

Heatsink 16 may be a bathtub heatsink in that it may provide a basin 45 in which printed board 14 and at least a portion of cover 12 (e.g. the sidewall 32 thereof) may rest or be otherwise situated. This basin 45 formed by heatsink 16 is discussed further below but may generally encapsulate the majority of printed board 14 and sidewall 32 of cover 12 therein to maximize thermal conductivity, as discussed herein. In particular, heatsink 16 may have a back plate 44, a perimeter of which may be generally surrounded by a perpendicularly-extending sidewall 46, which may extend upwards from back plate 44 towards floating cover 12. Sidewall 46 and back plate 44 may enclose or partially enclose a volume which may define basin 45 in which printed board 14 and at least a portion of cover 12 may be situated.

Heatsink 16 may further include one or more connectors 48, which may facilitate installation of module 10 into other systems or into proper position for operable use. For example, where module 10 is part of a larger system in aircraft, connectors 48 may facilitate module 10's installation into its designated position within the aircraft itself. Connectors 48 may also facilitate the alignment of connector 43 with its counterparts to allow for mating thereof and/or to secure the operable connection between connector 43 and its counterpart to prevent damage or unintentional separation thereof. According to one aspect, connectors 48 may include, but are not limited to, mechanical fasteners, alignment components such as alignment pins or the like, keying pins, or other similar connectors 48 and/or elements to facilitate connection of module 10 to an associated system as dictated by the desired implementation and the specific installation parameters thereof.

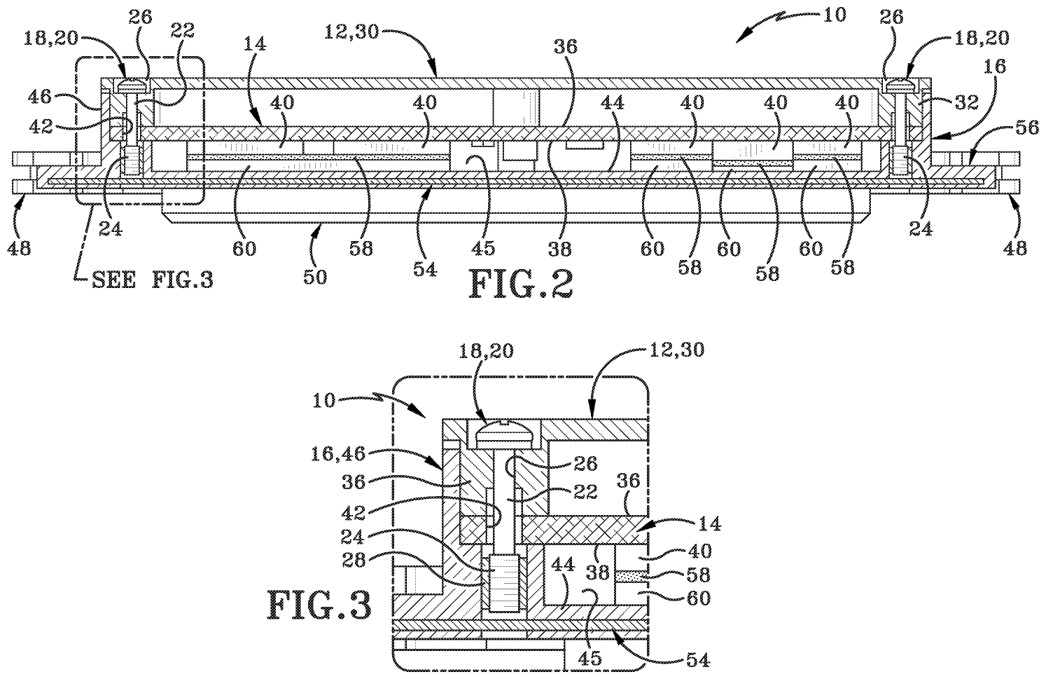

Heatsink 16 may further include one or more module standoffs, or module stands 50 (best seen in FIG. 2), which may extend outwardly from back plate 44 on the side opposite of sidewall 46. Module stands 50 may facilitate construction of module 10 by maintaining heatsink 16 in a level orientation while constructing module 10 to prevent errors or damage caused by an uneven or non-level heatsink 16 position during assembly. Module stands 50 may further help to protect and prevent damage to connector 43, connectors 48, and or other components of module 10 during assembly and installation thereof by providing, among other things, a stable support and clearance for such components during the manufacturing process.

Heatsink 16 back plate 44 may include one or more ribs 52, which may provide some additional structural support to module 10 and may also provide intermediate receivers 28 for mating cover 12 and printed board 14 thereto with captive screws 18, as discussed herein. Ribs 52 may generally be included on the printed board 14 side of heatsink 16 be placed or configured as dictated by the layout of active components 40 on printed board 14 as to not interfere or otherwise effect the use and performance thereof.

Heatsink 16, including back plate 44 and sidewall 46 thereof, may be constructed of any suitable material having sufficient thermal conductivity properties for the desired implementation. According to one aspect, heatsink 16 may be constructed out of aluminum or aluminum alloy. According to another aspect, heatsink 16 may be constructed from 6101 aluminum, which is known for its higher thermal conductivity.

As best seen in FIG. 2, heatsink 16 may have a core material layer 54, which may be a layer of high thermally conductive material encapsulated or otherwise contained within back plate 44 of heatsink 16. According to one example, core layer 54 may be Annealed Pyrolytic Graphite (APG), which may have three times the conductivity of copper while also having a density approximately equal to that of aluminum. According to another aspect, core layer 54 may be any other suitable material having a high thermal conductivity, as dictated by the desired implementation. Core layer 54 may be utilized to provide a thermal conduction path to direct heat generated by active components 40 through heatsink and to an exterior rail through rail interface 56, which may generally be the a portion of the surface of back plate 44, towards the peripheral edges thereof and exterior of sidewall 46. Although shown and described herein with a single rail interface 56, it will be understood that heatsink 16 may have an interface 56 with heat dissipating rails of an associated system at any suitable point, and may likewise include more than one rail interfaces 56 thereof, as desired.

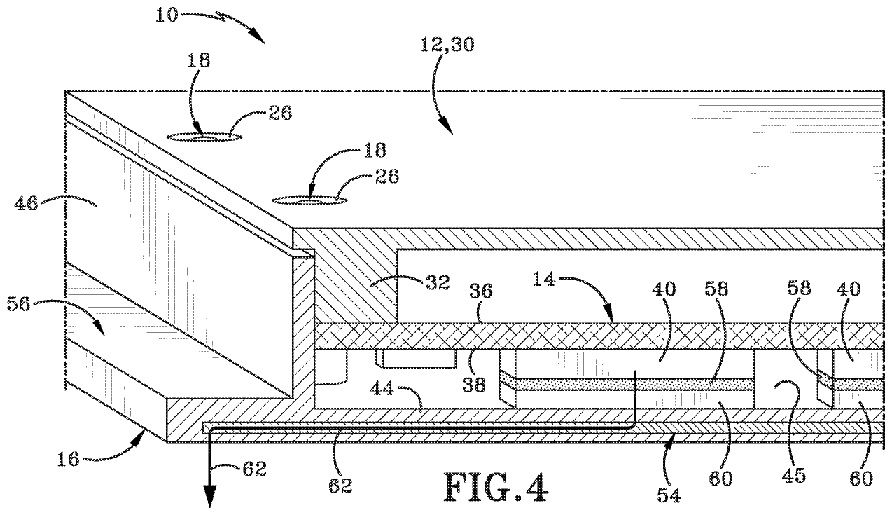

Heatsink 16 may further include a series of gap pads 58 and pedestals 60 extending from back plate 44 on the printed board 14 side thereof. Pedestals 60 may extend into basin 45 and may have varying heights dependent upon the thickness of a corresponding active component 40 and gap pad 58. Specifically, gap pads 58 and pedestals 60 may be numbered, sized, and aligned to contact each active component 40 carried by printed board 14 with each active component 40 adjacent and in contact with gap pads 58, which may then be connected to or otherwise in contact with pedestals 60. As pedestals 60 are part of heatsink 16, they are therefore in thermal communication with core layer 54. Utilizing these gap pads 58 and pedestals 60 in this configuration on heatsink 16 helps to minimize the tolerances between heatsink 16 and printed board 14, which then allows for the thermal gap pads 58 to cool active components 40 through the top of the component 40. Accordingly, this facilitates thermal management of module 10 as heat generated by active components 40 is transferred along the primary thermal path 64 (best seen in FIG. 4 and discussed below).

With reference to FIG. 4, as heat is generated by active components 40 on printed board 14, this heat must be managed to prevent damage to module 10. Current module designs, including those utilizing bathtub heatsinks, this heat is transferred from the components to the printed board that is hard bonded to the heatsink. The heat then transfers from the printed board to the heatsink.

Further, in such applications, the active components 40 tend to generate the most heat on the top side (e.g. the side away from printed board 14) thereof. The thermal interfaces, i.e. areas of high thermal resistance, at each of the two covers can cause higher temperatures at the component 40, which in turn can cause damage to the component 40 and shorten their overall lifespan. In addition, the use of thermal gap pads with the two cover designs can result in deflection of the covers overtime which may further result in the module no longer fitting in its allotted space in a larger system.

Through the utilization of a bathtub heatsink 16, module 10 may eliminate one of the thermal interfaces (i.e. the interface between the heatsink 16 and the second cover) which allows for a primary thermal path 62 that is more efficient. In particular, primary thermal path 62 directs heat generated from active components 40 out the top thereof and through gap pads 58 into pedestal 60. The heat is then dissipated to core layer 54 and out through rail interface 56 in the direction of arrow A shown therein. As gap pads 58 have a higher thermal conductivity than the standard liquid gap filler applications, the transfer of heat from active components 40 into pedestal 60 is more efficient and less heat dissipates into the cover 12. The bathtub heatsink 16 also allows for the use of the floating cover 12 given that the cover 12 is not a thermal path as compared with traditional two cover designs where heat can be transferred through both covers with less efficiency due to the cover-to-heatsink interfaces involved. This aspect may be further enhanced by the heatsink 16, including pedestals 60, in that tolerance stackup is reduced, further facilitating efficient thermal management through the use of gap pads 58.

As mentioned previously herein, current designs commonly use the printed board as a significant element in the thermal path, which then tends to require a metal-to-metal interface at the mounting locations where the printed board connects to the covers and to the heatsink. These metal-to-metal interfaces result in two dissimilar metals in contact with each other, which further leads to galvanic corrosion over time. The present module 10 allows for elimination of these metal-to-metal interfaces due to the efficiency of thermal path 62. Specifically, according to one aspect, with module 10 constructed as discussed herein, less than five percent of the heat generated by active components 40 transfers through the metal-to-metal interfaces, thus allowing a layer of metal to be removed with minimal impact on component 40 temperatures. This further enables the use of conductive ground pads 34 to tie electrically conductive elements of the printed board 14 to the cover 12. Thus, module 10 provides the elimination of dissimilar metal-to-metal interfaces and galvanic corrosion is prevented.

The use of electrically conductive ground pads 34 to eliminate metal-to-metal interfaces may further provide a benefit to module 10 over current modules in the ability to have a single finish on the cover 12, printed board 14, and heatsink 16, and that the single cover may further be selected as the optimal cover material. For example, printed board 14 may have a single optimal finish of electroless nickel immersion gold (ENiG) while cover 12 and/or heatsink 16 may be singularly finished with their optimal desired coating, such as nickel, gold, or any other suitable single finish while still complying with electrostatic discharge (ESD) safety requirements. Contrast this with current designs that include dissimilar metal-to-metal interfaces which require dual plating (e.g. dual finishes) on one or more of the printed board, heatsink, and/or covers to address the galvanic corrosion concerns, a process which can be very costly and is prone to defects.

Having thus described the elements, components, and advantages of module 10, the assembly and operation thereof will now be discussed.

Module 10 may generally be constructed of the three main components, namely cover 12, printed board 14, and heatsink 16 as discussed in detail herein. Accordingly, these components may be assembled individually through known processes. Specifically, cover 12 and heatsink 16 may be formed of metal and may be constructed using any suitable technique including, but not limited to, molding, casting, machining, or any other suitable method, or combinations thereof. Similarly, printed board 14 may be constructed according to suitable techniques and/or processes. Heatsink 16 may further be constructed to include core layer 54 therein for thermal transfer along primary thermal path 62 as previously discussed herein. Additionally, any other components, including connectors 48 or the like may be mated with heatsink 16 at this stage. During this construction phase, thermal gap pads 58 may be adhered or otherwise attached to pedestals 60 of heatsink 16.

Printed board 14 may then be printed with the appropriate circuitry and may be further connected or constructed to include all necessary testable components, such as caps, resistors, and the like, on the first side 36 thereof. Similarly, conductive ground pads 34 may be installed on first side 36 of printed board 14. Printed board 14 may then be further joined to active components 40, such as BGA components or the like, on the second side 38 thereof. Printed board 14 may likewise be joined with connectors, such as connectors 43, for operable mating with the system in which module 10 will be installed.

Prior to assembly into module 10, each component may then be given a single finish. As discussed previously herein, each of cover 12, printed board 14, and heatsink 16 may be singularly finished with the optimal coating for each element. No further finishing steps are required beyond this first finish.

Having formed and finished each of cover 12, printed board 14, and heatsink 16, module 10 may be assembled using a single set of captive screws 18 to secure the cover 12, printed board 14, and heatsink 16 together as a single unit. In particular, with reference to FIGS. 1 and 3, cover may be aligned with printed board 14 to properly position printed board within the space enclosed by sidewall 32 and to align apertures 26 and 42. Similarly, heatsink 16 may be aligned to allow insertion of printed board 14 and sidewall 32 of cover into the basin 45 defined by sidewall 46 and back plate 44 of heatsink 16. As part of aligning heatsink 16 with printed board 14 and cover 12, the alignment of active components 40 on second side 38 of printed board 12 with gap pads 58 and pedestals 60 should necessarily follow.

Once properly aligned, body 22 of captive screws 18 may be inserted thorough apertures 26 in cover 12 and through apertures 42 in printed board 14. The head 20 of captive screws 18 may prevent screws 18 from fully passing through apertures 26 in cover 12. Once inserted through apertures 26 and 42, the threads 24 of captive screws 18 may be engaged with the threaded receivers 28 carried by heatsink 16 and tightened into place. Once complete, module 10 may be installed into its allotted space within a larger system.

At its most basic, the assembly of module 10 requires only three steps once each component part, namely cover 12, printed board 14, and heatsink 16 are constructed. Specifically, following construction, module 10 need only to have the single finish applied to each component part; followed by alignment of the components to allow proper positioning of apertures 26 and 42 with receivers 28, and proper positioning of active components 40 with gap pads 58 and pedestals 60; and joining the cover 12, printed board 14, and heatsink 16 into a single unit using a single set of captive fasteners 18. From there, the only thing remaining would be to install the module 10 into the larger system in which it will be utilized when desired.

Contrast this with current modules and significant production time and cost may be saved, while simultaneously maximizing the producibility of module 10. For example, where module 10 may have three steps between construction and installation, prior modules require five steps or more, at a minimum. In particular, prior modules utilizing a two-cover design require a first finish on each component, followed by a second finish on each component to reduced galvanic corrosion. Then, the printed board is connected to the heatsink using a first set of fasteners, followed by the connection of the first cover to the printed board and heatsink with a second set of fasteners. Only then is the second cover mated with the printed board, heatsink, and first cover using a third set of fasteners. Accordingly, the module 10 of the present disclosure reduces time and cost associated with production, including the elimination of the second cover and reduction down to a single set of fasteners.

Once constructed, the operation of module 10 is similar to current operation in that module 10 may be installed into a larger system, which may include other components or elements as dictated by the desired implementation. According to one non-limiting example, module 10 may be or represent a single module within a system utilized for electronic warfare control such as threat tracking and avoidance, active and passive countermeasure management, and/or communications protocols, among others. In such an application, module 10 may be installed within a system carried by a vehicle, such as an aircraft, and may be integrated therein to communicate with one or more processors, one or more non-transitory storage mediums, and any other appropriate and/or necessary elements therefore. The elements may be integrated as legacy assets without undue modifications thereto. According to another aspect, module 10 may be employed as part of a custom designed system, and may be utilized for any suitable application as desired.

Accordingly, and in operation, module 10 may generate, receive, transmit, or otherwise utilize electrical signals between module 10 and other components of the associated system, or between individual components within module 10. As these electrical signals move through module 10, the active components 40 carried on printed board 14 generate heat which must be managed to prevent damage or failure of the module 10 and its component parts. Accordingly, module 10 may operate differently in that the heat generated by active components 40 may be directed away from the top thereof of via thermal gap pads 58 before being drawn into a pedestal 60 of the heatsink 16. From there, heat is further drawn to the core layer 54 of heatsink 16, which, due to its high thermal conductivity, further draws heat away from the active components 40 and towards a rail of the associated system through rail interface 62. Once the heat reaches the rail, it may be dissipated out and away from module 10 through any suitable or desired means. This directed primary heat path 62 may then allow module 10 to operate within an ideal temperature range, thus increasing the lifespan and efficiency thereof.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0. % of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

1. An electronic module comprising:
a cover;
a printed board with a first side and a second side;
at least one conductive ground pad on the first side of the printed board between the cover and the printed board;
at least one active component on the second side of the printed board;
a heatsink defining a basin for containing the printed board therein having at least one pedestal corresponding to each of the at least one active components;
at least one gap pad between a top of each of the at least one active component and the at least one corresponding pedestal of the heatsink; and
a plurality of captive fasteners operable to secure the cover, printed board, and heatsink together as a single unit.

2. The electronic module of claim 1 wherein the at least one gap pad is operable to draw heat away from the top of the at least one active component and into the corresponding pedestal of the heatsink.

3. The electronic module of claim 2 wherein the heatsink further comprises:
a thermally conductive material layer within the heatsink operable to direct heat away from the top of the at least one active component.

4. The electronic module of claim 3 wherein the thermally conductive material layer is Annealed Pyrolytic Graphite.

5. The electronic module of claim 3 wherein the heatsink further comprises:
at least one rail interface operable to connect to a rail of an associated system to dissipate heat from the thermally conductive material layer to the at least one rail.

6. The electronic module of claim 1 wherein the cover, printed board, and heatsink each have a single finish applied thereto.

7. The electronic module of claim 6 wherein the single finish of the cover, printed board, and heatsink are selected to be an optimal finish for each of the cover, printed board, and heatsink.

8. The electronic module of claim 1 wherein the module is free of dissimilar metal-to-metal interfaces.

9. The electronic module of claim 1 wherein the printed board further comprises:
at least one testable component on the first side thereof, wherein there are no testable components on the second side thereof.

10. The electronic module of claim 1 wherein the at least one active component further comprises:
a plurality of active components, wherein each of the plurality of active components are on the second side of the printed board.

11. The electronic module of claim 10 wherein the at least one corresponding pedestal of the heatsink further comprises:
a plurality of pedestals corresponding to the plurality of active components.

12. The electronic module of claim 11 wherein the at least one gap pad further comprises:
a plurality of gap pads between a top of each of the plurality of active components and the plurality of corresponding pedestals of the heatsink.

13. The electronic module of claim 12 wherein the plurality of gap pads are operable to draw heat away from the top of the plurality of active components and into the plurality of corresponding pedestals of the heatsink.

14. The electronic module of claim 13 wherein the heatsink further comprises:
a thermally conductive material layer within the heatsink operable to direct heat away from the top of the plurality of pedestals to at least one rail interface connected to a rail of an associated system to dissipate heat from the thermally conductive material layer to the at least one rail

15. The electronic module of claim 1 wherein the cover is a floating cover.

16. A method of thermal management of an electronic module comprising:
generating heat through the operation of at least one active component of a printed board;
drawing the heat through a thermal gap pad and away from a top of the at least one active component and into a corresponding pedestal of a heatsink;
directing the heat from the pedestal into a thermally conductive core layer of the heatsink; and
dissipating the heat out from a rail of an associated system through a rail interface of the heatsink.

17. The method of claim 16 further comprising:
securing a floating cover, the printed board, and the heatsink together as a single unit with a plurality of captive fasteners prior to generating heat through the operation of the at least one active component on the printed board.

18. The method of claim 17 further comprising:
applying a single finish to the cover, printed board, and heatsink.

19. The method of claim 18 wherein the single finish of the cover, printed board, and heatsink are selected to be an optimal finish for each of the cover, printed board, and heatsink.
